(19) United States
(12) Patent Application Publication
(10) Pub. No.: US 2016/0148704 A1
(43) Pub. Date: May 26, 2016

(54) ELECTRONIC DEVICE AND OPERATING METHOD THEREOF

(71) Applicant: Silicon Optronics, Inc., Hsinchu (TW)

(72) Inventor: Chun-Hung LIN, Hsinchu (TW)

(21) Appl. No.: 14/793,023

(22) Filed: Jul. 7, 2015

(30) Foreign Application Priority Data
Nov. 20, 2014 (TW) 103140178

(51) Int. Cl. G11C 17/00

(52) U.S. Cl. CPC G11C 17/00

(57) ABSTRACT

An embodiment of an electronic device is provided. The electronic device includes a read only memory (ROM) and a chip. The ROM includes a plurality of blocks. The chip includes a detecting unit, a configuration register unit, and an access interface. The detecting unit obtains a trigger signal according to an event. The configuration register unit provides a read address. The access interface loads a specific block of the blocks from the ROM according to the read address in response to the trigger signal. The configuration register unit updates the read address according to data of the specific block. Each of the blocks corresponds to an individual state of the event.

### CROSS REFERENCE TO RELATED APPLICATIONS

This Application claims priority of Taiwan Patent Application No. 103140178, filed on Nov. 20, 2014, the entirety of which is incorporated by reference herein.

### BACKGROUND OF THE INVENTION

1. Field of the Invention

The invention relates to an electronic device, and more particularly to an operating method for directly reading a read only memory (ROM) in an electronic device.

2. Description of the Related Art

In general, an electronic device is formed by various electronic components, to perform specific functions. In an electronic device, a host component can control the operations between the slave components and memories to perform specific functions, where the host and slave components are mostly integrated circuit (IC) chips. For example, a host chip (e.g. a microprocessor or a central processing unit (CPUs)) may set the control registers of the slave chips based on different operating conditions, i.e. the setting values that meet the current demand are configured to the control registers within the slave chips. If the setting values of the control registers are incorrect in the slave chip, the operations of the slave chip will err, and the electronic device will not work normally.

FIG. 1 shows a traditional electronic device 100. The electronic device 100 comprises a host chip 110, a read only memory (ROM) 120, and a slave chip 130. In the electronic device 100, the host chip 100 is operating according to the ROM code C_{ROM} that is pre-programmed and stored in the ROM 120. First, when the electronic device 100 is powered on, a processor 114 of the host chip 110 will load the ROM code C_{ROM} stored in the ROM 120 to a static random access memory (SRAM) 112. In some cases, the host chip 110 must be able to immediately set the control registers of the slave chip 130 to the correct values within a set time range. If not, the operation of the electronic device 100 is abnormal. In other words, working efficiency of the host chip 110 will also affect the correctness of the specific functions performed by the electronic device 100. For example, for an electronic device capable of performing image processing functions, if updating the image resolution in the continuous process of image processing is required, the host chip 110 needs to set the related control registers in the blank interval between two consecutive images. Traditionally, the electronic device 100 can use a shadow register 132 to avoid the above problems. Therefore, the processor 114 of the host chip 110 can update a level-1 register unit 131 of the shadow register 132 according to the setting values stored in the SRAM 112 at any time. Next, the shadow register 132 provides the setting values of the level-1 register unit 131 to a level-2 register unit 133 in the blank interval according to a control signal Ctrl, wherein the setting values stored in the level-2 register unit 133 are the real setting values for the control registers. Thus, the main circuit 134 will be able to perform the operation according to the correct setting values.

In the process for manufacturing electronic devices, a host chip having a SRAM and a processor will incur a higher production cost. Therefore, a chip capable of directly reading a ROM without a processor is desired.

### BRIEF SUMMARY OF THE INVENTION

An electronic device and an operating method thereof are provided. An embodiment of an electronic device is provided. The electronic device comprises a read only memory (ROM) and a chip. The ROM comprises a plurality of blocks. The chip comprises a detecting unit, a configuration register unit, and an access interface. The detecting unit obtains a trigger signal according to an event. The configuration register unit provides a read address. The access interface loads a specific block of the blocks from the ROM according to the read address in response to the trigger signal. The configuration register unit updates the read address according to data of the specific block. Each of the blocks corresponds to an individual slate of the event.

Furthermore, an embodiment of an operating method for an electronic device is provided, wherein the electronic device comprises a read only memory (ROM) and a chip. A trigger signal is obtained according to an event. In response to the trigger signal, a specific block is loaded from a plurality of blocks of the ROM to the chip according to a read address. The read address is updated according to data of the specific block. Each of the blocks corresponds to an individual state of the event.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows a traditional electronic device;

FIG. 2A and FIG. 2B show an electronic device according to an embodiment of the invention;

FIG. 3 shows an operating method of the electronic device of FIG. 2A and FIG. 2B;

FIG. 4A and FIG. 4B show an electronic device according to another embodiment of the invention;

FIG. 5 shows an operating method of the electronic device of FIG. 4A and FIG. 4B;

FIG. 6A and FIG. 6B show an electronic device according to another embodiment of the invention; and

FIG. 7 shows an operating method of the electronic device 600 of FIG. 6A and FIG. 6B.

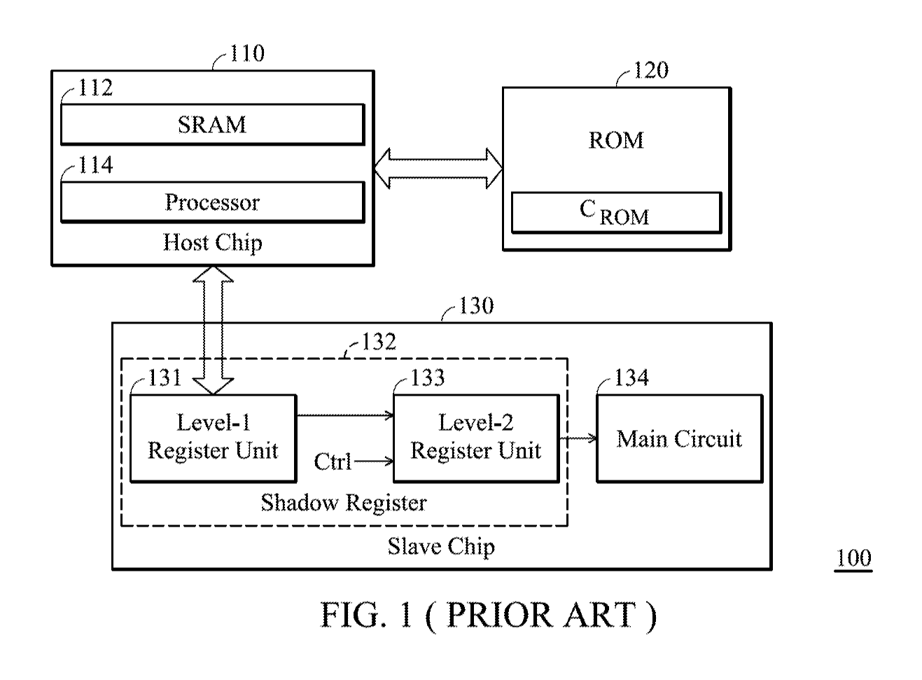

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

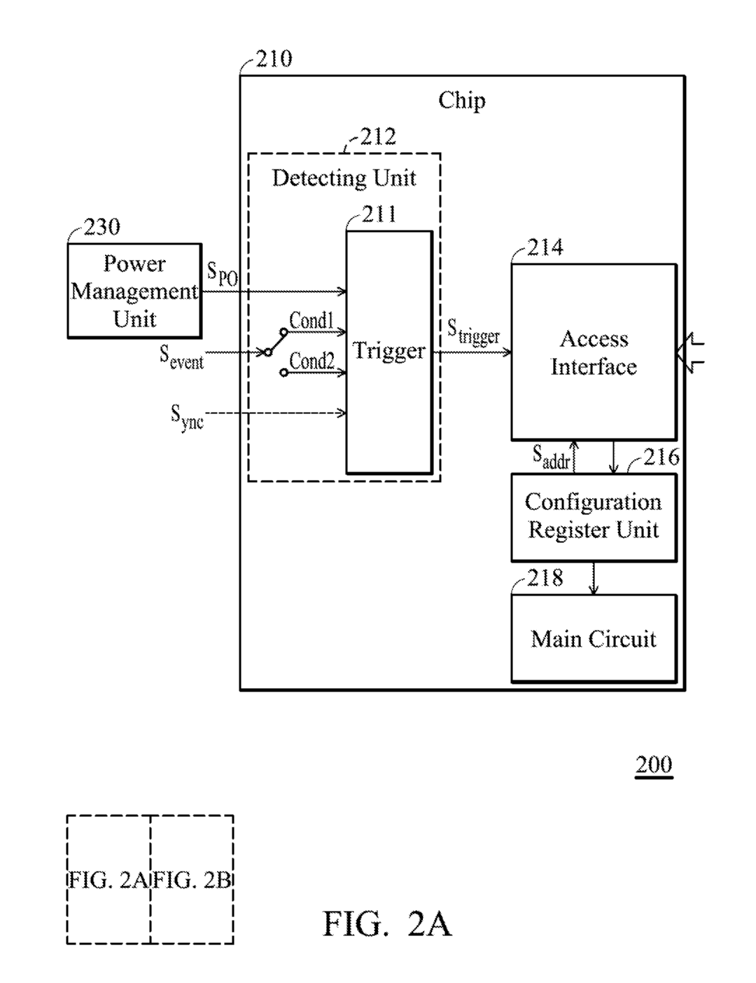

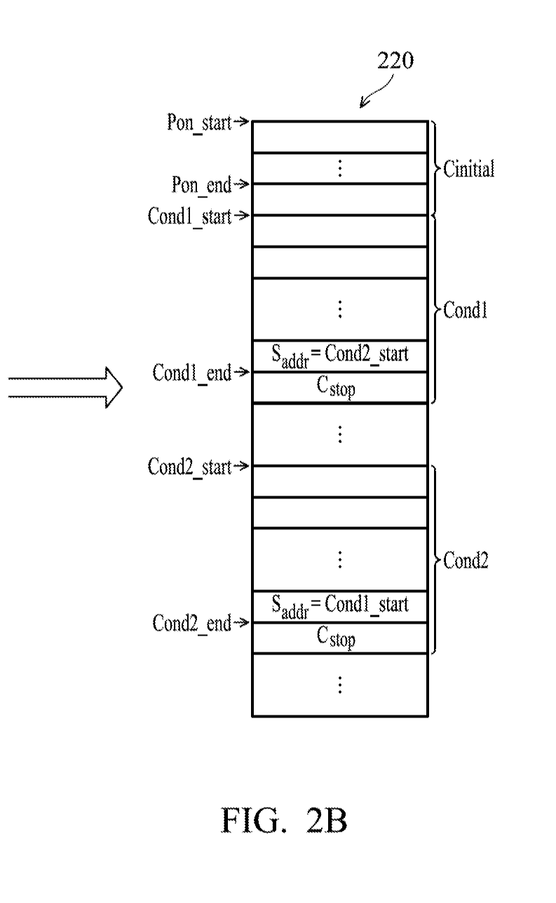

FIG. 2A and FIG. 2B show an electronic device 200 according to an embodiment of the invention. The electronic device 200 comprises a chip 210, a read only memory (ROM) 220, and a power management unit 230. The chip 210 comprises a detecting unit 212, an access interface 214, a configuration register unit 216 and a main circuit 218, wherein the main circuit 218 is capable of performing a specific function having two states. For example, the main circuit 218 can control image brightness, from a high brightness to a low brightness. Furthermore, the configuration register unit 216 comprises a plurality of control registers. When the electronic device 200 is powered on, the power management unit 230 provides a power-on signal S_{PO} to the chip 210. The detecting unit 212 comprises a trigger 211, which provides a trigger signal S_{trigger} to the access interface 214 according to the power-on signal S_{PO} from the power management unit 230 and an event Sₑᵥₑₙₜ from the external of internal devices of the electronic device 200, wherein the trigger signal S_{trigger} indicates that the electronic device 200 will operate in a specific state. Next, in response to the trigger signal S_{trigger}, the access interface 214 sequentially loads data of a specific block from the ROM 220 according to a start address S_{addr} from the configuration register unit 216, wherein a ROM code stored in the specific block comprises the setting values of the control registers corresponding to the trigger signal S_{trigger}. Next, the access interface 214 sequentially writes the setting value of the ROM code into the control registers of the configuration register unit 216. Thus, the main circuit 218 can complete the function corresponding to the trigger signal S_{trigger} according to correct settings of the configuration register unit 216. Furthermore, the detecting unit 212 also performs a synchronized trigger to the trigger signal S_{trigger} according to a synchronous signal S_{sync}. For example, assuming that the synchronous signal S_{sync} indicates a blank interval between two consecutive pictures, the detecting unit 212 will provide the trigger signal S_{trigger} to the access interface 214 when receiving the event Sₑᵥₑₙₜ in the blank interval between two consecutive pictures (i.e. the synchronous signal S_{sync} is present).

In FIG. 2A and FIG. 2B, the arrangement of the ROM code of the ROM 220 is stored according to the addresses and the setting values of the control, registers of the chip 210, wherein the positions storing the addresses and the setting values of the control registers are determined according to various applications and the size of the ROM 220. For example, the addresses and the setting values of the control registers are stored in the same addresses in the ROM 220. Furthermore, the addresses and the setting values of the control registers may be stored in different addresses in the ROM 220. In FIG. 2A and FIG. 2B, the ROM 220 comprises a plurality of blocks, wherein the data of each block comprises the addresses and the setting values of the control registers. In the embodiment, a block Cinitial is used to store the addresses of whole registers within the chip 210 and the initial values thereof when the electronic device 200 is powered on, wherein the block. Cinitial is arranged in a start address of the ROM 220, i.e. a start address Pon_start of the block Cinitial is the start address of the ROM 220 (e.g. 0x0000). Furthermore, a block Cond1 is used to store the addresses of the control registers of the chip 210 and the default values of the control registers when the electronic device 200 is operating in a first state (a default state). It should be noted that the block Cond1 is arranged in a position behind the block Cinitial, wherein a start address Cond1_start of the block Cond1 is the next address of the end address Pon_end of the block Cinitial. Furthermore, the end address Cond1_end of the block Cond1 is determined by a stop code Cₛₜₒₚ. Similarly, a block Cond2 is used to store the addresses of the control registers of the chip 210 and the setting values of the control registers when the electronic device 200 is operating in a second state. The block Cond2 is arranged in a position behind the block Cond1, and the end address Cond2_end of the block Cond2 is determined by the stop code Cₛₜₒₚ. It should be noted that, except for the initial block, each block stores at least the start address of another block. For example, in the block Cond1, the start address Cond2_start of the block Cond2 is stored in the last address of the end address Cond1_end of the block Cond1, and in the block Cond2, the start address Cond1_start of the block Cond1 is stored in the last address of the end address Cond2_end of the block Cond2. It should be noted that the location for storing the end address of another block is determined according to actual applications for each block.

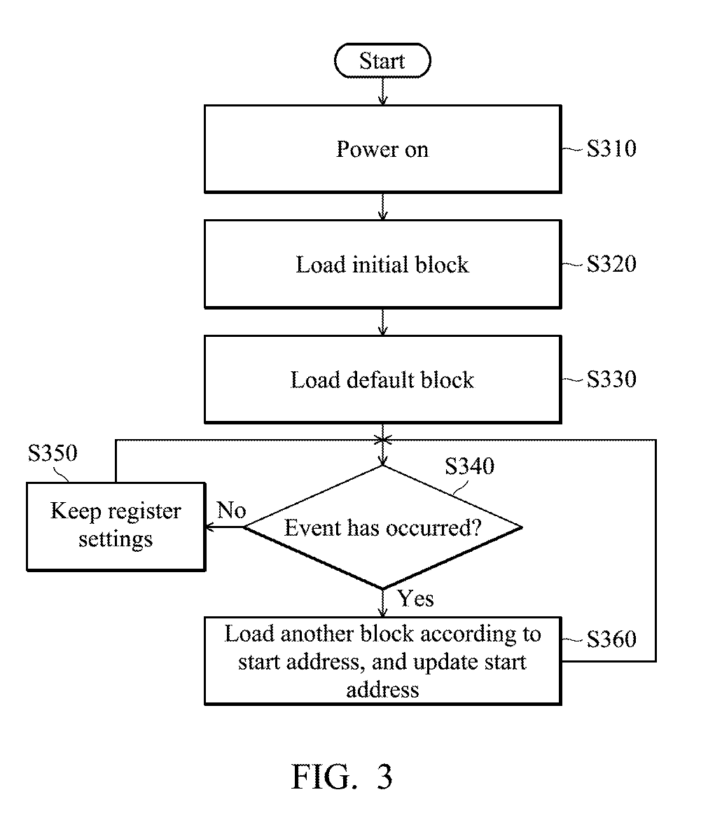

FIG. 3 shows an operating method of the electronic device 200 of FIG. 2A and FIG. 2B. Referring to FIGS. 2A, 2B and 3 together, first, in step S310, when the electronic device 200 is powered on, the power management unit 230 provides the power-on signal S_{PO} to the chip 210. Next, the detecting unit 212 provides the trigger signal S_{trigger} according to the power-on signal S_{PO}. When the trigger signal S_{trigger} indicates that the power-on signal S_{PO} is present, the configuration register unit 216 sets the start address S_{addr} that is used to reach the 220 to the start address Pon_start of the block Cinitial, so as to control the access interface 214 to read the block Cinitial from the start address 0x0000 of the ROM 220 (step S320), and then sets the control registers of the configuration register unit 216 to the initial values according to the read data. After reading the block Cinitial, the access interface 214 continues to read the block Cond1 (step S330), and then sets the control registers of the configuration register unit 216 to the default values according to the read data until the stop code Cₛₜₒₚ stored in the end address Cond1_end is read. Thus, the main circuit 218 can perform the operation conforming to the default state (i.e. the first state) according to the setting values of the configuration register unit 216 corresponding to the block Cond1, for example, the image brightness being set to a low brightness. Simultaneously, the start address Cond2_start of the block Cond2 stored in the block Cond1 is also stored in the configuration register unit 216, to serve as the start address S_{addr} the next reading of the ROM 220, i.e. the start address S_{addr} updated to the start address Cond2_start of the block Cond2. Next, in step S340, the detecting unit 212 determines whether an event Sₑᵥₑₙₜ has occurred (i.e. the event Sₑᵥₑₙₜ is present). In one embodiment, the event Sₑᵥₑₙₜ may be a toggle signal. If no such event Sₑᵥₑₙₜ has taken place, the setting values of the control registers of the configuration register unit 216 will not be updated, and the electronic device 200 continues performing the operation of the current state (step S350). If the event Sₑᵥₑₙₜ has taken place, the detecting unit 212 provides the trigger signal S_{trigger}. When the trigger signal S_{trigger} indicates that the event Sₑᵥₑₙₜ has occurred, the configuration register unit 216 provides the start address S_{addr} to the access interface 214, wherein the start address S_{addr} is set to the start address Cond2_start of the block Cond2. Next, the access interface 214 is controlled to read the block Cond2 from the ROM 220 according to the start address S_{addr} (step S360), and the control registers of the configuration register unit 216 are set to the setting values of the block Cond2 according to the read data until the stop code Cₛₜₒₚ stored in the end address Cond2_end is read. Thus, the main circuit 218 can perform the operation conforming to the second state, such as the image brightness being set to a high brightness. Simultaneously, the start address Cond1_start of the block Cond1 stored in the block Cond2 is also stored in the configuration register unit 216, to serve as the start address S_{addr} for the next reading of the ROM 220, i.e. the start address S_{addr} updated to the start, address Cond1_start of the block Cond1. Therefore, in the embodiment, when the chip 210 detects that the event has been triggered, the setting values of the control registers of the configuration register unit 216 that need to be updated will automatically be loaded from the start address of another block of the ROM 220 via the access interface 214 until reading the stop code Cₛₜₒₚ.

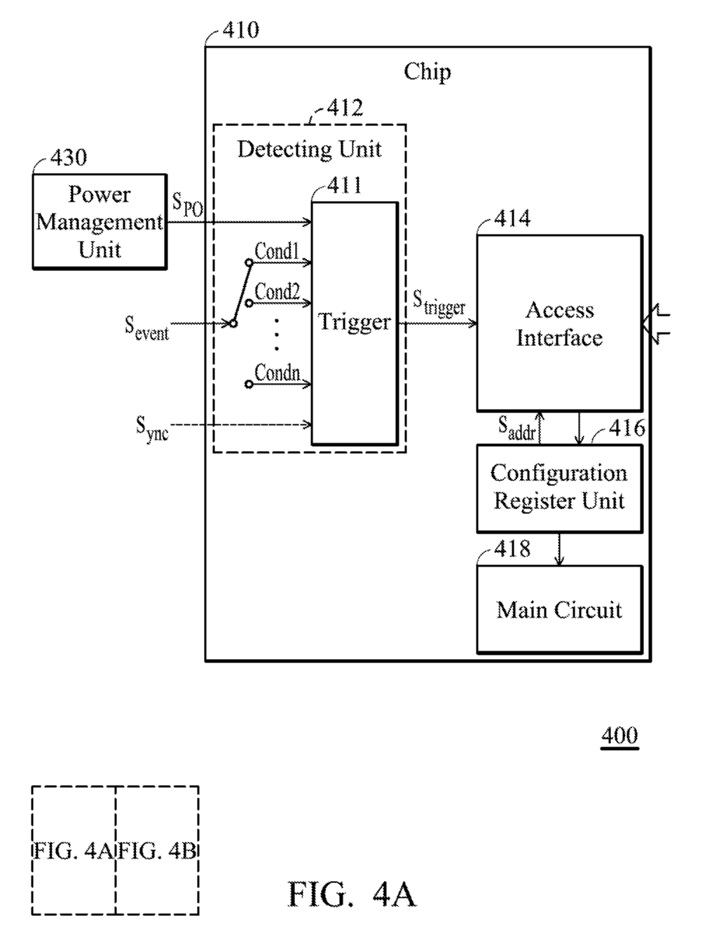

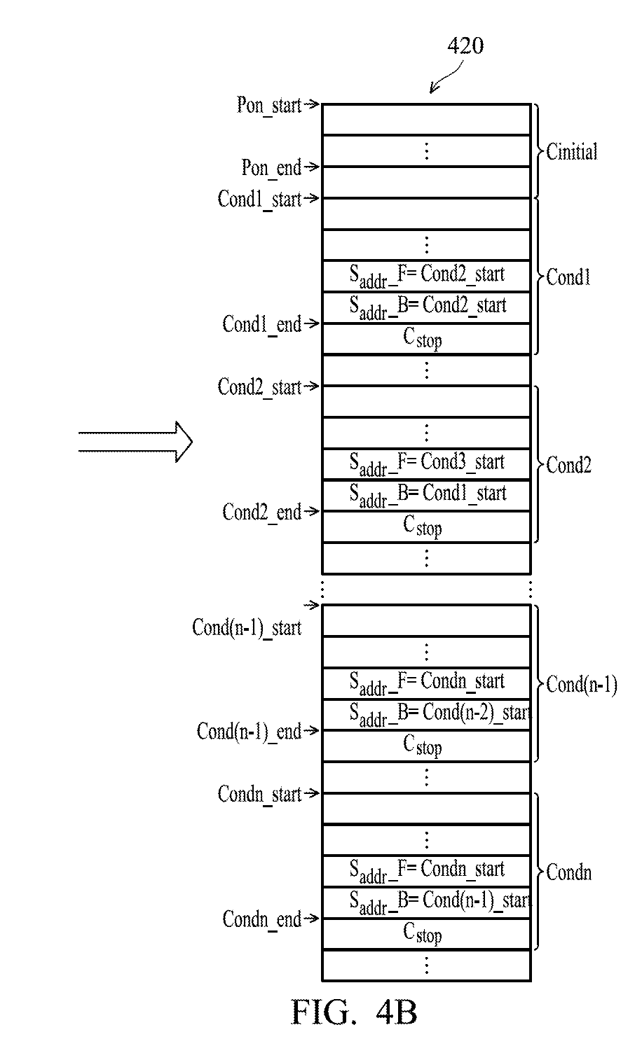

FIG. 4A and FIG. 4B show an electronic device 400 according to another embodiment of the invention. The electronic device 400 comprises a chip 410, an ROM 420, and a power management unit 430. The chip 410 comprises a detecting unit 412, an access interface 414, a configuration register unit 416 and a main circuit 418, wherein the main circuit 418 is capable of performing a specific function having n states. In the ROM 420, a block Cinitial is used to store the addresses of whole registers within the chip 410 and the initial values thereof when the electronic device 400 is powered on, wherein the block Cinitial is arranged in a start address of the ROM 420. Furthermore, a block Cond1 is used to store the addresses of the control registers of the chip 410 and the default values of the control registers when the electronic device 400 is operating in a first state (a default state). It should be noted that the block Cond1 is arranged in a position behind the block Cinitial. Similarly, a block Cond2 is used to store the addresses of the control registers and the setting values thereof when the electronic device 400 is operating in a second state, a block Cond(n−1) is used to store the addresses of the control registers and the setting values thereof when the electronic device 400 is operating in a (n−1)^{th} state, and a block Condn is used to store the addresses of the control registers and the setting values thereof when the electronic device 400 is operating in a n^{th} state. It should be noted that the positions from the block Cond2 to the block Condn are determined according to actual applications. As described above, when the electronic device 400 is powered on, the block Cinitial and the block Cond1 of the ROM 420 are sequentially loaded to the chip 410. Next, in response to the event Sₑᵥₑₙₜ, the chip 410 will switch from the first state to the n^{th} slate in a first order or a second order. In the embodiment, the first order is forward, and the second order is backward. Therefore, each block comprises a corresponding forward start address S_{addr}_{_}_{F} and a corresponding backward start address S_{addr}_{_}_{F}. For example, when the chip 410 is operating in a first state, the chip 410 can switch to a second state according to a forward order, or continue in the first state according to a backward order. Therefore, in the block Cond1, the forward start address S_{addr}_{_}F is set to the start address Cond2_start of the block Cond2, and the backward start address S_{addr}_{_}B is set to the start address Cond1_start of the block Cond1. Furthermore, when the chip 410 is operating in the second state, the chip 410 can switch to a third state according to the forward order, or to the first state according to the backward order. Therefore, in the block Cond2, the forward start address S_{addr}_{_}F is set to the start address Cond3_start of the block Cond3, and the backward start address S_{addr}_{_}B is set to the start address Cond1_start of the block Cond1.

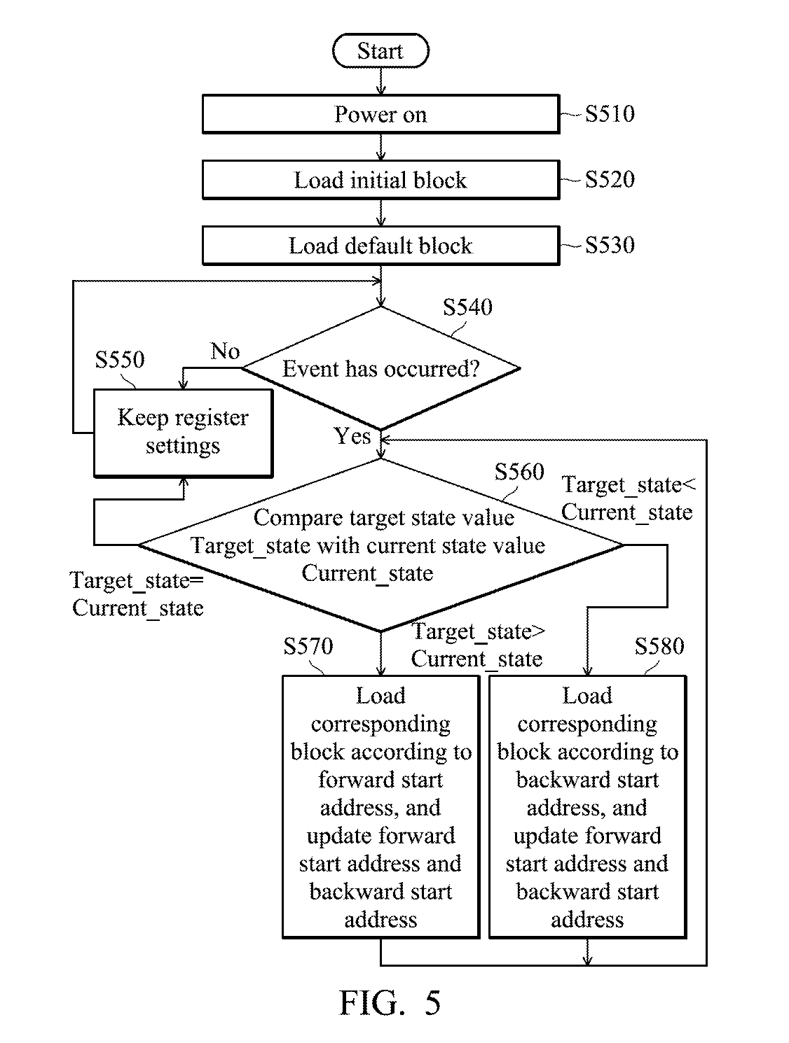

FIG. 5 shows an operating method of the electronic device 400 of FIG. 4A and FIG. 4B. Referring to FIGS. 4A, 4B and 5 together, first, in step S510, when the electronic device 400 is powered on, the power management unit 430 provides the power-on signal S_{PO} to the chip 410. Next, the detecting unit 412 provides the trigger signal S_{trigger} according to the power-on signal S_{PO}. When the trigger signal S_{trigger} indicates that the power-on signal S_{PO} is present, the configuration register unit 416 sets the start address S_{addr} that is used to read the ROM 420 to the start address Pon_start of the block Cinitial, so as to control the access interface 414 to read the block Cinitial from the start address 0x0000 of the ROM 420 (step S520), and then sets the control registers of the configuration register unit 416 to the initial values according to the read data. After reading the block Cinitial, the access interface 414 continues to read the block Cond1 (step S530), and then sets the control registers of the configuration register unit 416 to the default, values according to the read data until the stop code Cₛₜₒₚ stored in the end address Cond1_end is read. Thus, the main circuit 418 can perform the operation conforming to the default state (i.e. the first state) according to the setting values corresponding to the block Cond1 in the configuration register unit 416, such as the image brightness being set to a first level. Simultaneously, the forward the stmt address S_{addr}_{_}F and the backward the start address S_{addr}_{_}B stored in the block Cond1 are also stored in the configuration register unit 416, to serve as the start address S_{addr} for the next reading of the ROM 420. Moreover, the configuration register unit 416 sets a current state value Current_state (e.g. Current_state=1) according to the first state. Next, in step S540, the detecting unit 412 detects whether the event Sₑᵥₑₙₜ has taken place, wherein the event Sₑᵥₑₙₜ has a target state value Target_state. If the event Sₑᵥₑₙₜ has not occurred, the setting values of the control registers the configuration register unit 416 will not be updated, and the electronic device 400 continues to perform the operation of the current state (step S550). If it is detected that the event Sₑᵥₑₙₜ has occurred, the detecting unit 412 provides the trigger signal S_{trigger} having the current state value Target_state. Next, in step 560, the configuration register unit 416 compares the target state value Target_state with the current state value Current_state. When the target state value Target_state is equal to the current state value Current_state (i.e. Target_state=Current_state), the setting values of the control registers of the configuration register unit 416 will not be updated, and the electronic device 400 continues to perform the operation of current state (step S550). Furthermore, when the target state value Target_state is larger than the current state value Current_state (i.e. Target_state>Current_state), the configuration register unit 416 provides the start address S_{addr} to the access interface 414 according to the forward start address S_{addr}_{_}F, thus the access interface 414 is controlled to read the block corresponding to the forward start address S_{addr}_{_}F from the ROM 420 according to the start address S_{addr} (step S570), and then the control registers of the configuration register unit 416 are set to the setting values of the block according to the read data until the stop code Cₛₜₒₚ stored in the end address of the block is read. Simultaneously, the configuration register unit 416 updates the target state value Target_state, the backward start address S_{addr}_{_}B, and the forward start address S_{addr}_{_}F according the data of the block. Next, the flow returns to step S560, the target state value Target_state and the updated current state value Current_state are compared, and then the subsequent steps are performed until the target state value Target_state is equal to the current state value Current_state. Furthermore, when the target state value Target_state is smaller than the current state value Current_state (i.e. Target_state<Current_state), the configuration register unit 416 provides the start address S_{addr} to the access interface 414 according to the backward start address S_{addr}_{_}B, thus the access interface 414 is controlled to read the block corresponding to the backward start address S_{addr}_{_}B from the ROM 420 according to the start address S_{addr} (step S580), and then the control registers of the configuration register unit 416 are set to the setting value of the block according to the read data until the stop code Cₛₜₒₚ stored in the end address of the block is read. Simultaneously, the configuration register unit 416 updates the target state value Target_state, the backward start address S_{addr}_{_}B, and the forward start address S_{addr}_{_}F according to the block. Next, the flow returns to step S560, and the target state value Target_state and the updated current state value Current_state are compared, and then the subsequent steps are performed until the target state value Target_state is equal to the current state value Current_state. For example, if the current state value Current_state is 1 and the target state value Target_state is 3, the chip 410 will load the block Cond2 and the block Cond3 in sequence, and then perform the operation corresponding to the state (e.g. the image brightness is increased from a first level to a second level, and then to a third level in sequence) until the current state value Current_state is switched to 3. Therefore, in the embodiment, when the chip 410 detects that the event has been triggered, the setting values of the control registers of the configuration register unit 416 to be updated will be loaded from the corresponding blocks via the access interface 414 in sequence, and the corresponding operations are performed.

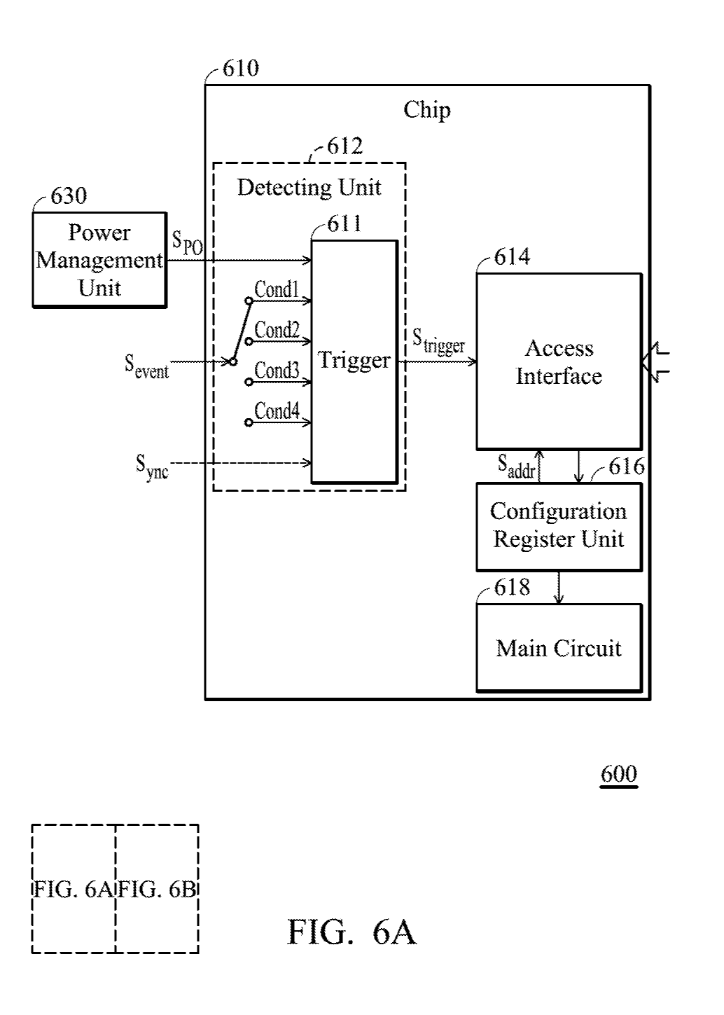

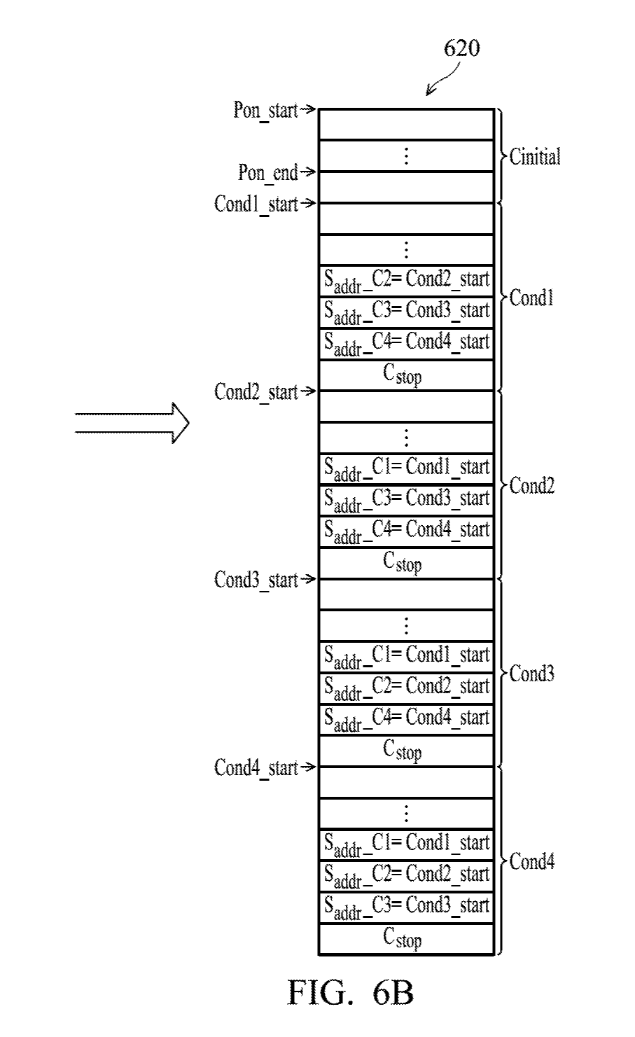

FIG. 6A and FIG. 6B show an electronic device 600 according to another embodiment of the invention. The electronic device 600 comprises a chip 610, an ROM 620, and a power management unit 630. The chip 610 comprises a detecting unit 612, an access interface 614, a configuration register unit 616, and a main circuit 618, wherein the main circuit 618 is capable of performing a specific function having four states. As described above, when the electronic device 600 is powered on, the block Cinitial and the block Cond1 of the ROM 620 are sequentially loaded to the chip 610. Next, according to the state assigned by the event Sₑᵥₑₙₜ, the chip 610 loads the corresponding block directly from the ROM 620. Therefore, in each block, it has the start address S_{addr} of other blocks. For example, in the ROM 620, the block Cond1 comprises the start address Cond2_start of the block Cond2, the start address Cond3_start of the block Cond3, and the start address Cond4_start of block Cond4. Furthermore, the block Cond2 comprises the start address Cond1 _start of the block Cond1, the start address Cond3_start of the block Cond3, and the start address Cond4_start of the block Cond4.

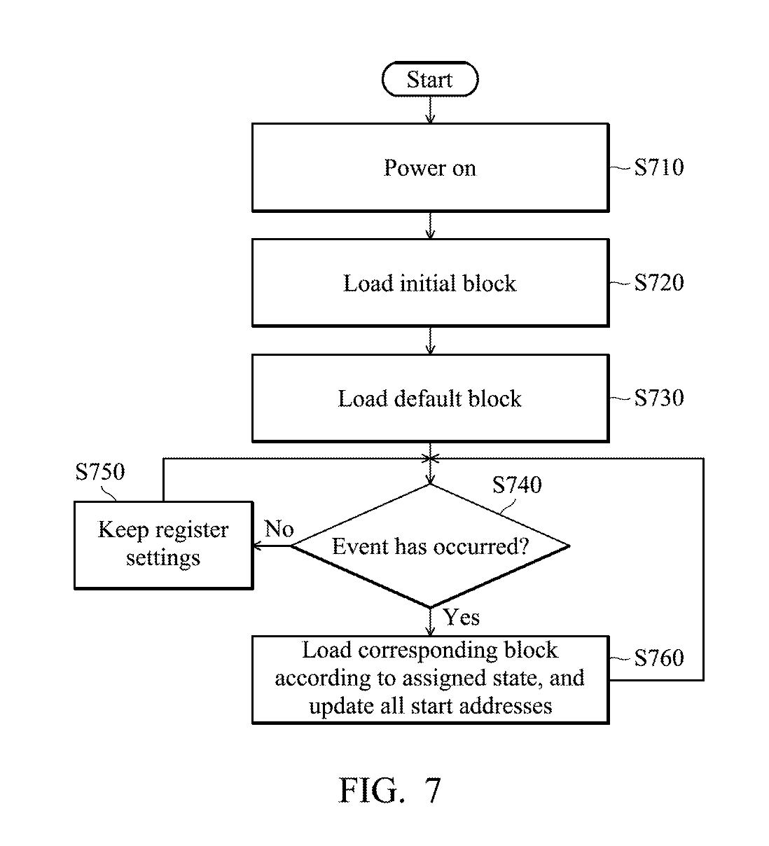

FIG. 7 shows an operating method of the electronic device 600 of FIG. 6A and FIG. 6B. Referring to FIGS. 6A, 6B and 7 together, first, in step S610, when the electronic device 600 is powered on, the power management unit 630 provides the power-on signal S_{PO} to the chip 610. Next, the detecting unit 612 provides the trigger signal S_{trigger} according to the power-on signal S_{PO}. When the trigger signal S_{trigger} indicates that the power-on signal S_{PO} is present, the configuration register unit 616 sets the start address S_{addr} that is used to read the ROM 620 to the start address Pon_start of the block Cinitial, so as to control the access interface 614 to read the block Cinitial from the start address 0x0000 (step S720), and then the control registers of the configuration register unit 616 are set to the initial values according to the read data. After reading the block Cinitial, the access interface 614 continues to read the block Cond1 (step S730), and the control registers of the configuration register unit 616 are set to the default values according to the read data until the stop code Cₛₜₒₚ stored in the end address Cond1_end is read. Thus, the main circuit 618 can perform the operation conforming to the default state (i.e. the first state) according to the setting values of the configuration register unit 216 corresponding to the block Cond1, for example, the image brightness being set to a first level. Simultaneously, the start addresses (e.g. S_{addr}_{_}C2, S_{addr}_{_}C3 and S_{addr}_{_}C4) of the other blocks stored in the block Cond1 are also stored in the configuration register unit 616, to serve as the start address S_{addr} for the next reading of the ROM 620. Next, in step S740, the detecting unit 612 will detect whether the event Sₑᵥₑₙₜ has occurred, wherein the event Sₑᵥₑₙₜ will indicate which state is to be switched. In the absence of an event Sₑᵥₑₙₜ occurring, the settings of the configuration register unit 616 will not be updated, and the electronic device 600 continues to perform the operation of the current state (step S750). If it is detected that the event Sₑᵥₑₙₜ has taken place, the detecting unit 612 provides the trigger signal S_{trigger}. Next, in step 760, the configuration register unit 616 provides the start address S_{addr} of the corresponding block from the start addresses of the other blocks to the access interface 614 according to the state assigned by the event Sₑᵥₑₙₜ, so as to control the access interface 614 to read the block from the ROM 620 (step S760), and the control registers of the configuration register unit 616 are set to the setting values of the block according to the read data until the stop code stored in the end address of the block is read. Simultaneously, according to the data of the block, the start addresses S_{addr} of the other blocks are also to be updated in the configuration register unit 616. For example, when the chip 610 is operating in the first state and the event Sₑᵥₑₙₜ indicates that the chip 610 will switch to the third state, the configuration register unit 616 provides the start address S_{addr} of the block Cond to the access interface 614 according to the data (S_{addr}_{_}C3=Cond3_start) of the block Cond1 loaded before, so as to control the access interface 614 to read the block Cond3 from the ROM 620. Therefore, in the embodiment, when the chip 610 detects that the event has been triggered, the setting values of the control register of the configuration register unit 616 to be updated will automatically be loaded from the corresponding blocks of the ROM 620 via the access interface 614, and the corresponding operations are performed.

According to the embodiments, any chip in which the setting values of control registers need to be set according to various states or conditions can complete the functions of the electronic device without the microprocessor or central processor unit (CPU), and without increasing the amount of control registers, thus decreasing the production cost of the electronic device. For example, in a monitoring system, the electronic device may trigger the chip according to the current brightness condition, so as to load the pre-defined exposure value, gain value, or values of other image processing from the ROM, to achieve optimum recording effects.

Furthermore, in non-complex application systems, the circuits of the entire system can be simpler and save power by reducing the demands on the microprocessor or CPU. According to the embodiments, control registers can be completed by the chip itself.

Moreover, updating all control registers can also be synchronized to system requirements, and can be completed within a reasonable time without using the shadow registers, thereby reducing the chip size. Furthermore, the arrangement of the blocks within the ROM are arranged to correspond to the addresses and the setting values of the control registers of the chip, making it easy for developers to understand and modify.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed Is:

1. An electronic device, comprising:
a read only memory (ROM), comprising a plurality of blocks; and
a chip, comprising:
a detecting unit, obtaining a trigger signal according to an event;
a configuration register unit, providing a read address; and
an access interface, loading a specific block, of the blocks from the ROM according to the read address in response to the trigger signal,
wherein the configuration register unit updates the read address according to data of the specific block,
wherein each of the blocks corresponds to an individual state of the event.

2. The electronic device as claimed in claim 1, wherein when the trigger signal indicates that a first state of the event is present, the data of the specific block comprises a first register setting value corresponding to the first state, and a start address of the block corresponding to a second state of the event, wherein the configuration register unit updates the read address according to the start address.

3. The electronic device as claimed in claim 2, wherein the chip further comprises:
a main circuit, performing a specific function corresponding to the first state according to the first register setting value.

4. The electronic device as claimed in claim 1, further comprising:
a power management unit, providing a power-on signal when the electronic device is powered on,
wherein the detecting unit obtains the trigger signal further according to the power-on signal and the event.

5. The electronic device as claimed in claim 4, wherein when the trigger signal indicates that the power-on signal is present, the data of the specific block comprises an initial register setting value, a default register setting value corresponding to a default state of the event, and a start address of the block corresponding to the next state of the event, wherein the configuration register unit updates the read address according to the start address.

6. The electronic device as claimed in claim 5, wherein the chip further comprises:
a main circuit, performing a specific function corresponding to the default state according to the initial register setting value and the default register setting value.

7. The electronic device as claimed in claim 1, wherein when the trigger signal indicates a first state of the event is present, the data of the specific block comprises a first register setting value corresponding to the first state, a first start address of the block corresponding to a second state of the event, and a second start address of the block corresponding to a third state of the event.

8. The electronic device as claimed in claim 7, wherein the second state of the event is the next state of the first state, and the third state of the event is the last state of the first state.

9. The electronic device as claimed in claim 7, wherein the configuration register unit selects the first start address or the second start address to update the read address according to the next trigger signal.

10. The electronic device as claimed in claim 1, wherein when the trigger signal indicates that a first state of the event is present, the data of the specific block comprises a first register setting value corresponding to the first state, and a start address of each of the blocks corresponding to the other states of the event except for the first state.

11. The electronic device as claimed in claim 10, wherein the configuration register unit selects one of the start addresses to update the read address according to the next trigger signal.

12. The electronic device as claimed in claim 1, wherein an end address of each of the blocks is determined by a stop code.

13. The electronic device as claimed in claim 1, wherein the detecting unit provides the trigger signal to the access interface according to a synchronous signal.

14. An operating method for an electronic device, wherein the electronic-device comprises a read only memory (ROM) and a chip, and the operating method comprises:
obtaining a trigger signal according to an event;
in response to the trigger signal, loading a specific block from a plurality of blocks of the ROM to the chip according to a read address; and
updating the read address according to data of the specific block,
wherein each of the blocks corresponds to an individual state of the event.

15. The operating method as claimed in claim 14, wherein when the trigger signal indicates that a first state of the event is present, the data of the specific block comprises a first register setting value corresponding to the first state, and a start address of the block corresponding to a second state of the event, wherein the read address is updated according to the start address.

16. The operating method as claimed in claim 15, further comprising:
performing a specific function corresponding to the first state according to the first register setting value, by the chip.

17. The operating method as claimed in claim 14, wherein when the trigger signal indicates that the electronic device is powered on, the data of the specific block comprises an initial register setting value, a default register setting value corresponding to a default state of the event, and a start address of the block corresponding to the next state of the event, wherein the read address is updated according to the start, address.

18. The operating method as claimed in claim 17, further comprising:
performing a specific function corresponding to the default state according to the initial register setting value and the default register setting value, by the chip.

19. The operating method as claimed in claim 14, wherein when the trigger signal indicates a first state of the event is present, the data of the specific block comprises a first register setting value corresponding to the first state, a first start address of the block corresponding to a second state of the event, and a second start address of the block corresponding to a third state of the event, wherein the second state of the event is the next state of the first state, and the third state of the event is the last state of the first state.

20. The operating method as claimed in claim 19, further comprising:
selecting the first start address or the second start address to update the read address according to the next trigger signal; and
performing a specific function corresponding to the first state according to the first register setting value, by the chip.

21. The operating method as claimed in claim 14, wherein when the trigger signal indicates that a first state of the event is present, the data of the specific block comprises a first register setting value corresponding to the first state, and a start address of each of the blocks corresponding to the other states of the event except for the first state.

22. The operating method as claimed in claim 21, further comprising:
selecting one of the start addresses to update the read address according to the next trigger signal; and
performing a specific function corresponding to the first state according to the first register setting value, by the chip.

23. The operating method as claimed in claim 14, wherein an end address of each of the blocks is determined by a stop code.

24. The operating method as claimed in claim 14, wherein the step of obtaining the trigger signal according to the event further comprises:
obtaining the trigger signal according to a power-on signal; or
obtaining the trigger signal according to the event and a synchronous signal.
